(19) United States
(12) Patent Application Publication
(10) Pub. No.: US 2024/0030288 A1
(43) Pub. Date: Jan. 25, 2024

(54) Heterojunction Bipolar Transistor

(71) Applicant: Nippon Telegraph and Telephone Corporation, Tokyo (JP)

(72) Inventors: Manabu Mitsuhara, Tokyo (JP); Yuta Shiratori, Tokyo (JP)

(21) Appl. No.: 18/255,280

(22) PCT Filed: Dec. 17, 2020
(86) PCT No.: PCT/JP2020/047121

§ 371 Date: May 31, 2023

(51) Int. Cl. H01L 29/10; H01L 29/66; H01L 29/08

(52) U.S. Cl. CPC H01L 29/1004; H01L 29/66318; H01L 29/0821; H01L 29/0817

(57) ABSTRACT

A hetero-junction bipolar transistor includes a substrate made of InP, and a sub-collector layer, a collector layer, a base layer, an emitter layer, and an emitter cap layer formed on the substrate. The base layer is made up of a first base layer on the collector layer side and a second base layer on the emitter layer side. The first base layer has a constant Sb molar composition ratio in the thickness direction. In the second base layer, the Sb molar composition ratio increases in the thickness direction toward the emitter layer.

### CROSS-REFERENCE TO RELATED APPLICATIONS

This application is a national phase entry of PCT Application No. PCT/JP2020/047121, filed on Dec. 17, 2020, which application is hereby incorporated herein by reference.

### TECHNICAL FIELD

The present invention relates to a hetero junction bipolar transistor made up of a group III-V compound semiconductor.

### BACKGROUND

In recent years, with the progress of Internet of things (IoT) and cloud computing, demands for high speed communication and large capacity communication have rapidly increased. In order to respond to these requests in communication, utilization of a frequency band in the vicinity of 1 THz called a millimeter wave or a terahertz band has been studied, and a part of the frequency band has already been put into practical use. In order to utilize a frequency band near 1 THz, an electronic circuit operating at a high speed is required. Since a hetero junction bipolar transistor on an InP substrate is excellent in high-frequency characteristics, it has been extensively studied as an electronic device used in electronic circuits that operate at high speeds (see, for example, NPL 1).

A layer structure of the hetero junction bipolar transistor can be roughly divided into a single hetero junction bipolar transistor (SHBT) in which the same semiconductor material is used for a base layer and a collector layer, and a semiconductor material with a large bandgap is used for an emitter layer, and a double hetero junction bipolar transistor (DHBT) in which a semiconductor material with a larger bandgap than the base layer is used not only for the emitter layer but also for the collector layer.

Although the single hetero junction bipolar transistor has the advantage that the layer structure is relatively easy to manufacture and there is no potential barrier which obstructs electron transfer between the base layer and the emitter layer, the collector breakdown voltage is low because the band gap of the material used for the collector layer is small. On the other hand, in the double hetero junction bipolar transistor, since a material having a large band gap can be used for the collector layer, it is possible to avoid the problem that the collector breakdown voltage is small, but there is another problem. The problem will be described with reference to FIGS. 15, 16, and 17. As an example of the double hetero junction bipolar transistor fabricated on an InP substrate, a bipolar transistor using InGaAs and GaAsSb for the base layer will be described.

FIG. 15 schematically shows a band arrangement in a thermal equilibrium state (at a zero bias) when a base layer 304 is formed of InGaAs doped with p-type impurities at a high concentration and a collector layer 303 and an emitter layer 305 are formed of InP doped with n-type impurities at a low concentration.

FIG. 16 schematically shows a band arrangement in a thermal equilibrium state (at a zero bias) when the base layer 304 is formed of GaAsSb doped with p-type impurities at a high concentration, and the collector layer 303 and the emitter layer 305 are formed of InP doped with n-type impurities at a low concentration.

First, a problem in the case where the base layer 304 is formed of InGaAs will be described. A double hetero-structure in which both sides of the base layer 304 made of InGaAs are sandwiched by the collector layer 303 made of InP and the emitter layer 305 has a band arrangement of type I as shown in FIG. 15, and the bottom energy position of the conduction band is higher in the collector layer 303 than in the base layer 304. In this case, a potential barrier exists when electrons move from the base layer 304 to the collector layer 303. This potential barrier is called band discontinuity in the conduction band.

In general, electrons in the conduction band do not become a large obstacle to electron transfer even if there is a small potential barrier at room temperature. Specifically, if the band discontinuity of the conduction band is about 0.1 eV, which is about four times the product of the Boltzmann constant and temperature (kBT=26 meV at 300 K), electron transfer is not affected by the band discontinuity.

However, when the base layer 304 is made of InGaAs (bandgap=0.75 eV) lattice-matched to InP, the band discontinuity in the conduction band is 0.2 eV or more. Therefore, so-called current blocking occurs in which electron transfer from the base layer 304 to the collector layer 303 is suppressed. Therefore, when the base layer 304 is made of InGaAs, a lamination structure made of the collector layer 303, the base layer 304, and the emitter layer 305 is rarely used as a double hetero junction bipolar transistor.

The potential barrier when electrons move from the base layer to the collector layer can be made small by forming the collector layer from a semiconductor material having a band gap smaller than that of InP. However, although this case is an improvement over the single hetero junction bipolar transistor, there arises a problem that the breakdown voltage of the collector layer against the voltage application is reduced.

The problem occurring when the InGaAs is used for the base layer can be solved by using GaAsSb for the base layer as will be described below.

The band arrangement shown in FIG. 16 is a double hetero structure in which the base layer 304 made of GaAsSb is sandwiched between the collector layer 303 made of InP and the emitter layer 305, and this layer configuration takes a band arrangement of type II. In this case, the band discontinuity of the conduction band at the interface between the emitter layer 305 and the base layer 304 serves as a potential barrier when electrons move. The band discontinuity between the emitter layer 305 and the base layer 304 made of GaAsSb is smaller than the band discontinuity between the base layer made of InGaAs and the emitter layer made of InP, and a potential barrier to electron transfer is small. The potential barrier between the emitter layer 305 and the base layer 304 made of GaAsSb can be reduced by replacing InP of the emitter layer 305 with a material having a large band gap such as InGaP, InAIP, or InAlAs.

That is, in the layer structure having the band arrangement shown in FIG. 16, even if InP of the emitter layer 305 is replaced with a material having a larger band gap, the breakdown voltage against the voltage application does not decrease. Therefore, by replacing InGaAs of the base layer of the double hetero junction bipolar transistor with GaAsSb, the problem of a potential barrier which prevents electron movement can be solved, and breakdown voltage against voltage application can be secured.

From the above, in the double hetero junction bipolar transistor using GaAsSb as a base layer, improvement in device characteristics, more specifically improvement in current gain cut-off frequency, can be expected as compared with the case of using InGaAs. However, the current gain cut-off frequency of actually manufactured devices has no large difference compared to those using InGaAs as the base layer, and there is a problem that the advantage of the band arrangement is not utilized.

### CITATION LIST

### Patent Literature

PTL 1—Japanese Patent Application Publication No. 2003-086602
PTL 2—Japanese Patent Application Publication No. 2011-009330

### Non Patent Literature

NPL 1—C. R. Bolognesi et al., “InP/GaAsSb DHBTs for THz Applications and Improved Extraction of their Cut-off Frequencies,” IEEE International Electron Devices Meeting, 723-726, 2016.
NPL 2—C. R. Bolognesi et al., “InP/GaAsSb/InP Double HBTs: A New Alternative for InP-Based DHBTs,” IEEE Transactions on Electron Devices, vol. 48, No. 11, pp. 2631-2639, 2001.
NPL 3—M. Peter et al., “Band Gaps and Band Offsets in deposited GaAs 1-ySbySbyon InP grown by metalloorganic chemical vapor deposition,” applied Physics letters, vol. 74, No. 3, PP. 410-412 1999.
NPL 4—J. Y. T. Huang et al., “Characteristics of strained GaAs_{1-y}Sby (0.16≤y≤0.69) quantum wells on InP substrates,” JOURNAL OF PHYSICS D: APPLIED PHYSICS, vol. 40, pp. 7656-7661, 2007.

### SUMMARY

### Technical Problem

In a double hetero junction bipolar transistor using GaAsSb as a base layer, factors that cause expected device characteristics include problems in terms of materials with GaAsSb and the influence of a potential barrier between the base layer and the collector layer on electron transfer. The material problems and the influence of the potential barrier will be described below.

First, a material problem of GaAsSb will be described. In the p-type GaAsSb layer, it is known that the mobility of holes is lower than that of the p-type InGaAs layer, even if a doping amount is the same as that of the p-type InGaAs layer (for example, see PTL 1). For this reason, when GaAsSb is used for the base layer, if a base sheet resistance of the same degree as that of InGaAs is obtained, GaAsSb needs to be doped with p-type impurities at a higher concentration than InGaAs.

Specifically, when InGaAs is used for the base layer, a p-type impurity concentration as high as about 5×10¹⁹ cm⁻³ is often used. However, in order to obtain a base sheet resistance similar to this, GaAsSb is required to have a higher p-type impurity concentration. However, it is difficult to ensure crystal growth and reliability by doping GaAsSb with a high concentration of p-type impurities.

Furthermore, GaAsSb has a problem of mobility. In the hetero junction bipolar transistor, a factor related to the current gain cut-off frequency is the mobility of electrons in the base layer doped with p-type impurities at a high concentration. The lower the mobility is, the longer it takes for electrons to pass through the base layer, and the more the current gain cut-off frequency decreases. Although the values of the mobility of electrons in the p-type impurity—doped layer cannot be measured directly from experiments, an approximate value can be obtained by analyzing the device characteristics. Specifically, it is reported that the electron mobility of C-doped p-type GaAsSb obtained by analyzing device characteristics is about ¼ to ⅕ of that of p-type InGaAs (see NPL 2).

As described above, when GaAsSb is used for the base layer, it is necessary to dope very high p-type impurities, and there is a material problem with GaAsSb that mobility is smaller.

Next, the influence of the potential barrier between the base layer and the collector layer on the electron transfer will be described. Although the band arrangement of the double hetero junction bipolar transistor shown in FIG. 16 is in a thermal equilibrium state in which no bias voltage is applied, the bias voltage is applied at the time of operation. FIG. 17 schematically shows a band arrangement when a bias voltage is applied to the layer structure of FIG. 16. Since the spatial charge of the collector layer 303 is not compensated for at the time of operation, when band discontinuity between the base layer 304 and the collector layer 303 is large, band curvature occurs in the collector layer 303, and a potential notch structure is formed at the bottom of a conduction band (for example, see PTL 2). When electrons are accumulated by the potential notch structure, the traveling time of the electrons in the collector layer increases, and as a result, the current gain cut-off frequency decreases.

In order to reduce the influence of the potential notch structure, band discontinuity between the base layer 304 and the collector layer 303 may be reduced by changing the Sb molar composition ratio of GaAsSb. For this purpose, it is necessary to correctly know the change of band discontinuity GaAsSb in the conduction bands of GaAsSb and InP due to the Sb molar composition ratio.

However, it is difficult to obtain the energy of the bottom of the conduction band from calculation when the Sb molar composition ratio of GaAsSb is changed even at present (for example, see NPL 3 and NPL 4). Therefore, it is difficult to quantitatively determine the Sb molar composition ratio of GaAsSb which can reduce the band discontinuity in the conduction band of GaAsSb and InP near room temperature which is the operating temperature. Therefore, at present, there is a problem that expected device characteristics cannot be obtained in a hetero junction bipolar transistor using GaAsSb as a base layer.

Embodiments of the present invention can solve the problems described above, and an object thereof is to obtain expected device characteristics in a hetero junction bipolar transistor using GaAsSb as a base layer.

### Solution to Problem

A hetero junction bipolar transistor according to embodiments of the present invention includes a substrate made of InP; a collector layer which is formed on the substrate and made of a group III-V compound semiconductor; a base layer which is formed on the collector layer and made of a group III-V compound semiconductor containing Ga, As, and Sb; and an emitter layer which is formed on the base layer and made of a group III-V compound semiconductor different from that of the base layer, in which an Sb molar composition ratio of the base layer decreases from the emitter layer side to the middle of the base layer in a thickness direction and is constant from the middle of the base layer to the collector layer.

### Advantageous Effects of Embodiments of the Invention

As described above, according to embodiments of the present invention, since the Sb molar composition ratio of the base layer made of the group III-V compound semiconductor containing Ga, As, and Sb is reduced in a thickness direction from the emitter layer side to the middle of the base layer and is made constant from the middle of the base layer to the collector layer, expected device characteristics can be obtained in a hetero junction bipolar transistor using GaAsSb for the base layer.

### BRIEF DESCRIPTION OF THE DRAWINGS

FIG. 1 is a cross-sectional view showing the configuration of a hetero junction bipolar transistor according to an embodiment of the present invention.

FIG. 2 is a band diagram showing a band arrangement in a thermal equilibrium state around a base layer in the layer structure of the hetero junction bipolar transistor according to an embodiment.

FIG. 3 is a characteristic diagram showing a change in a miscibility gap of InGaAsSb due to a growth temperature.

FIG. 4 is a band diagram showing the band arrangement of a hetero-structure of GaAsSb and InP.

FIG. 5 is a characteristic diagram showing the results of an inter-band transition between type I and type II at 300 K.

FIG. 6 is a characteristic diagram showing a change in band discontinuity in the conduction band of the GaAsSb/InP hetero-structure at 300 K, due to the Sb molar composition ratio of GaAsSb.

FIG. 7 is a characteristic diagram showing a change in band discontinuity in the conduction band between an emitter layer made of In_{0.8}Ga_{0.2}P and a base layer made of GaAsSb, due to the Sb molar composition ratio of GaAsSb.

FIG. 8 is a characteristic diagram showing band discontinuity of the conduction band between InGaP and GaAsSb when the Ga molar composition ratio of InGaP is changed to 0, 0.10, 0.15, 0.20, 0.25, and 0.30.

FIG. 9 is a characteristic diagram showing the change in lattice distortion due to the Ga molar composition ratio of InGaP on InP.

FIG. 10 is a characteristic diagram showing the change in lattice distortion due to the Sb molar composition ratio of GaAsSb on InP.

FIG. 11 is a characteristic diagram showing changes in lattice distortion in layers when the Sb molar composition ratio of the GaAsSb base layer and the Ga molar composition ratio of the InGaP emitter layer are changed.

FIG. 12 is a characteristic diagram showing the measurement results of the X-ray diffraction pattern of a sample in which GaAsSb with a tensile distortion of 1% (Sb molar composition ratio of 0.36) is grown on InP with varying thicknesses.

FIG. 13 is a characteristic diagram showing the measurement results of microscopic PL mapping for a sample grown with GaAsSb having a tensile distortion of 1% and a thickness of nm and 46 nm.

FIG. 14 is a band diagram showing an energy position of the bottom of the conduction band when using a GaAsSb base layer having the structure described using FIG. 11.

FIG. 15 is a band diagram showing a band arrangement in a thermal equilibrium state when a base layer is made of InGaAs doped with p-type impurities at a high concentration and a collector layer and an emitter layer are made of InP doped with n-type impurities at a low concentration.

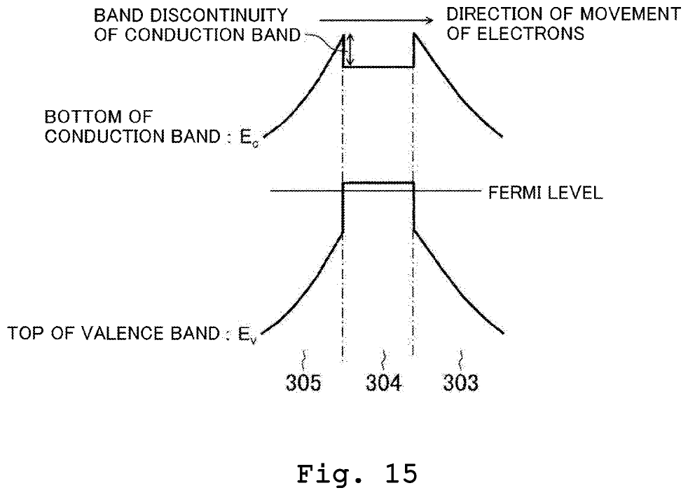

FIG. 16 is a band diagram showing a band arrangement in a thermal equilibrium state when a base layer is made of GaAsSb doped with p-type impurities at a high concentration and a collector layer and an emitter layer are made of InP doped with n-type impurities at a low concentration.

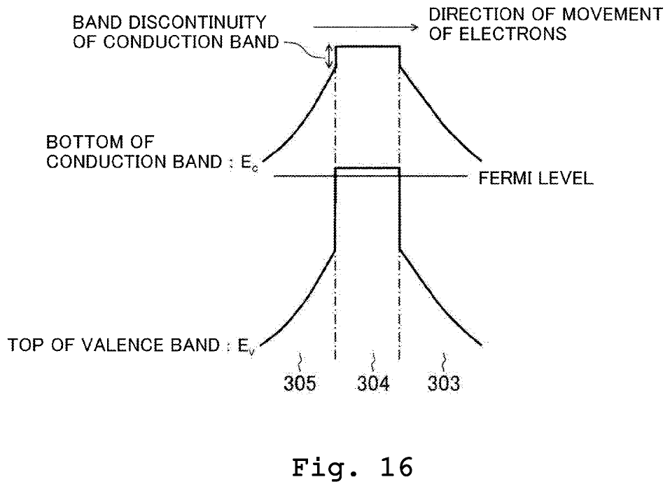

FIG. 17 is a band diagram showing a band arrangement when a bias voltage is applied when a base layer is made of GaAsSb doped with p-type impurities at a high concentration and a collector layer and an emitter layer are made of InP doped with n-type impurities at a low concentration.

### DETAILED DESCRIPTION OF ILLUSTRATIVE EMBODIMENTS

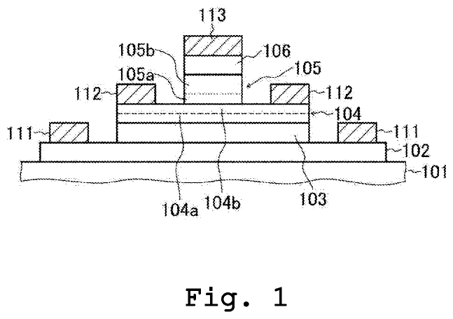

Hereinafter, a hetero-junction bipolar transistor according to an embodiment of the present invention will be described with reference to FIG. 1.

The hetero-junction bipolar transistor includes a substrate 101 made of InP, a sub-collector layer 102, a collector layer 103, a base layer 104, an emitter layer 105, and an emitter cap layer 106 formed on the substrate 101. The hetero-junction bipolar transistor is a so-called double hetero-junction bipolar transistor.

The sub-collector layer 102 is formed on the substrate 101 and is made of a group III-V compound semiconductor. The sub-collector layer 102 can be a laminated structure of, for example, an InP layer having a thickness of 200 nm and an InGaAs layer having a thickness of 100 nm. The InP layer can have an n-type carrier concentration of 5×10¹⁹ cm⁻³, the InGaAs layer can have an n-type carrier concentration of 3×10¹⁹ cm⁻³, and an In molar composition ratio can be set to 0.53.

The collector layer 103 is formed on the sub-collector layer 102 and is made of a group III-V compound semiconductor. The collector layer 103 can be made of InP, for example, a thickness can be set to 100 nm, and an n-type carrier concentration can be set to 3×10¹⁶ cm⁻³.

The base layer 104 is formed on the collector layer 103 and is made of a group III-V compound semiconductor containing Ga, As, and Sb. The base layer 104 can be made of GaAsSb. The base layer 104 is made of a first base layer 104a on the collector layer 103 side and a second base layer 104b on the emitter layer 105 side. The first base layer 104a has a constant Sb molar composition ratio in the thickness direction. In the second base layer 104b, the Sb molar composition ratio increases in the thickness direction toward the emitter layer 105.

In this configuration, the Sb molar composition ratio of the base layer 104 decreases from the emitter layer 105 side to the middle of the base layer 104 in the thickness direction and is constant from the middle of the base layer 104 to the collector layer 103. For example, the Sb molar composition ratio of the base layer 104 can be in the range of 0.49 or more to 0.53 or less in the vicinity of the interface with the emitter layer 105 in the thickness direction, and in the range of 0.3 or more to 0.4 or less in the vicinity of the interface with the collector layer 103. The thickness of the base layer 104 can be about 35 nm or less.

For example, the first base layer 104a can have a thickness of 10 nm, a p-type carrier concentration of 6×10¹⁹ cm⁻³, and a Sb molar composition ratio of 0.36. The second base layer 104b can be configured to have a thickness of 20 nm, a p-type carrier concentration of 6×10¹⁹ cm⁻³, and a Sb molar composition ratio of 0.36 to 0.49 continuously increasing toward the emitter layer 105 side.

The emitter layer 105 is formed on the base layer 104 and is made of a group III-V compound semiconductor different from that of the base layer 104. The emitter layer 105 can be made of an InGaP layer 105a made of InGaP in a part in the thickness direction and an upper emitter layer 105b formed on the InGaP layer 105a. The Ga molar composition ratio of the InGaP layer 105a can be configured to increase toward the base layer 104 in the range of greater than 0 and 0.25 or less.

For example, the InGaP layer 105a can be configured to have a thickness of 10 nm, an n-type carrier concentration of 3×10¹⁷ cm⁻³, and a Ga molar composition ratio continuously decreased from 0.20 to 0 toward the upper emitter layer 105b. The upper emitter layer 105b is made of InP, the thickness can be set to 10 nm, and the n-type carrier concentration can be set to 3×10¹⁷ cm⁻³.

An emitter cap layer 106 is formed on the emitter layer 105 and is made of a group III-V compound semiconductor. The emitter cap layer 106 can be made of, for example, InGaAs, and can have a thickness of 200 nm, an n-type carrier concentration of 3×10¹⁹ cm⁻³, and an In molar composition ratio of 0.53.

The collector layer 103 and the base layer 104 are formed in a predetermined mesa structure (collector mesa), and a collector electrode 111 is formed on the sub-collector layer 102 around this mesa structure. The collector electrode 111 is ohmic-connected to the sub-collector layer 102 and electrically connected to the collector layer 103. The emitter layer 105 and the emitter cap layer 106 are formed in a predetermined mesa structure (emitter mesa), and the base electrode 112 is formed on the base layer 104 (second base layer 104b) around the mesa structure. The base electrode 112 is electrically connected to the base layer 104 (the second base layer 104b) by ohmic connection. An emitter electrode 113 which is ohmic-connected to the emitter cap layer 106 is formed on the emitter cap layer 106.

For example, the above-mentioned layers are sequentially epitaxially grown on the substrate 101 by a well-known organometallic vapor phase epitaxy method. In addition, each layer can be epitaxially grown by a molecular beam epitaxy method, an organic metal molecular beam epitaxy method, a gas source molecular beam epitaxy method, and the like, without being limited to the organic metal vapor phase epitaxy method. Then, an emitter electrode material is deposited on the emitter cap layer 106 to form a metal film. Then, the metal film is patterned by a known lithography technique to form an emitter electrode 113.

Next, the emitter cap layer 106 and the emitter layer 105 are selectively etched by a known etching technique using the formed emitter electrode 113 as a mask, and an emitter mesa is formed. The dimensions of the emitter mesa in plan view can be 0.5 μm×2 μm. For example, first, etching is performed up to the vicinity of the InGaP layer 105a of the emitter layer 105. Then, the pattern formed in this way is covered with a protective film made of an insulating material, and thereafter, the InGaP layer 105a can be completely etched to expose the second base layer 104b, thereby forming an emitter mesa.

After the emitter mesa is formed as described above, a base electrode material is deposited on the emitter mesa while leaving a protective film to form a metal film, and the metal film is patterned by a known lift-off method by removing the protective film, thereby forming the base electrode 112.

Next, the base layer 104 and the collector layer 103 are patterned by known lithography and etching techniques to form a collector mesa, and a region in which the sub-collector layer 102 is exposed is formed on the side of the collector mesa. Then, a collector electrode 11 is formed in a region in which the sub-collector layer 102 is exposed. Finally, the hetero-junction bipolar transistor can be fabricated by performing inter-element isolation using a known etching technique.

According to the above-described embodiment, the problem of electron transfer from the base layer made of GaAsSb to the collector layer to be hetero-junction is solved, and expected device characteristics can be obtained in a hetero-junction bipolar transistor using GaAsSb as the base layer.

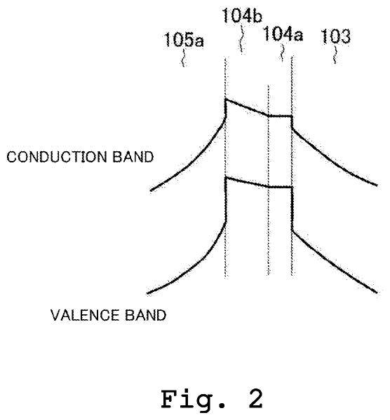

FIG. 2 shows a band arrangement in a thermal equilibrium state around the base layer 104 in the layer structure of the hetero-junction bipolar transistor according to the above-described embodiment. The energy difference of the bottom of the conduction band is about 60 MeV between the InGaP layer 105a and the second base layer 104b, is about 40 MeV between the first base layer 104a and the collector layer 103, and is smaller than the energy difference 100 meV of the bottom of the conduction band considered that a potential barrier and a potential notch structure in the electron transfer become problems.

The current gain cut-off frequency of the hetero-junction bipolar transistor according to the embodiment described above is 320 GHz when a bias voltage between the collector and the emitter is 1.2 V. For comparison, in the hetero-junction bipolar transistor for comparison made of only GaAsSb in which the base layer has a thickness of 30 nm, the p-type carrier concentration has 6×10¹⁹ cm⁻³, and the Sb molar composition ratio continuously increases from 0.36 to 0.49, the current gain cut-off frequency is 280 GHz.

The reason why the current gain cut-off frequency is higher in the embodiment than in the case of the hetero-junction bipolar transistor for comparison is that the passing time of electrons in the base layer is shortened. As described above, according to the embodiment, the current gain cut-off frequency of the hetero-junction bipolar transistor can be increased.

As described above, according to the first embodiment, since the Sb molar composition ratio of the base layer made of GaAsSb is reduced in the thickness direction from the emitter layer side to the middle of the base layer and is made constant from the middle of the base layer to the collector layer 103, expected device characteristics can be obtained by the hetero-junction bipolar transistor of this type.

Embodiments of the present invention reduce the influence on electron transfer of a problem occurring when GaAsSb is used for the base layer of a double hetero-junction bipolar transistor, thereby leading out the potential of the base layer made of GaAsSb and facilitating the improvement of device characteristics. A relationship between the band arrangement in the conduction bands of GaAsSb and InP at room temperature and the Sb molar composition ratio of GaAsSb, which has been difficult to quantitatively determine, will be described below.

As described above, one of the factors of difficulty in improving device characteristics in a double hetero-junction bipolar transistor using GaAsSb as a base layer is caused by a small electron mobility of GaAsSb. The Sb molar composition ratio is largely related to the electron mobility of GaAsSb. First, this will be described.

GaAsSb is lattice-matched to InP when the molar composition ratio of Sb is about 0.49. Therefore, when GaAsSb is used in a device on an InP substrate, a value close to 0.49 is often used as the Sb molar composition ratio of GaAsSb. However, for GaAsSb having a Sb molar composition ratio close to the condition of lattice matching with InP, it is known that compositional separation is likely to occur (see, for example, references 1 and 2). This compositional separation is influenced by the miscibility gap (see, for example, reference 3).

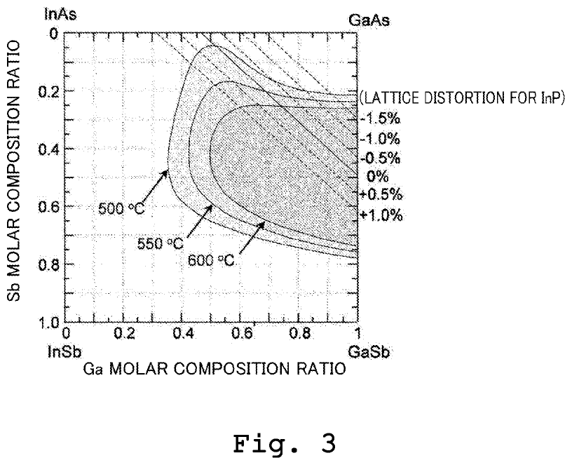

FIG. 3 shows the change of the miscibility gap of InGaAsSb according to the growth temperature. In FIG. 3, when the composition of InGaAsSb is inside the missing gap, the compositional separation is likely to occur. The composition on a right axis in FIG. 3 corresponds to GaAsSb. In InGaAsSb, the lattice constant changes depending on the molar composition ratio of Ga and Sb, and the lattice distortion applied to the crystal changes. The oblique lines in the drawing show contour lines from −1.5% (tensile distortion) to +1.0% (compressive distortion) as the lattice distortion applied in InGaAsSb.

FIG. 3 shows that the miscibility gap becomes smaller as the growth temperature becomes higher from 500° C. to 550° C. and 600° C. Therefore, by increasing the growth temperature, the influence of the compositional separation can be reduced. However, since the composition region of GaAsSb (the composition region in which the lattice distortion is close to 0%), which is close to the condition of lattice matching with InP, is located near the center of the miscibility gap even if the growth temperature is set to 600° C., it is difficult to avoid the effects of compositional separation. Due to the effect of the compositional separation, it is considered that, in GaAsSb which is close to the condition of lattice matching with InP, a minute region having a different composition is formed in the crystal to disturb the movement of electrons, which is considered to be one of the factors of lowering the electron mobility.

In order to reduce the influence of the miscibility gap, it is effective to increase the growth temperature and the V/III ratio. However, it is difficult to raise the growth temperature of GaAsSb because of the tendency of desorption of group V elements from the surface. In addition, since GaAsSb contains Sb which tends to cause surface segregation in the configuration of GaAsSb, it is difficult to increase the V-III ratio. Therefore, it is difficult to improve the electron mobility by suppressing the influence of the compositional separation in GaAsSb, as long as the Sb molar composition ratio close to the condition of lattice matching with InP is used.

The reason why the electron mobility of GaAsSb is small is that alloy scattering in addition to the compositional separation is also affected. Alloy scattering is proportional to y×(1−y) when the Sb molar composition of GaAsSb is set as y, and the larger this value is, the more likely the decrease in electron mobility occurs. Here, the molar composition at which y×(1−y) is maximized is a case of y=0.5. A case where GaAsSb is lattice-matched to InP is a case where the Sb molar composition ratio (y) is around 0.49 as described above, which is close to y=0.5 where alloy scattering is maximum. Therefore, when GaAsSb having a composition lattice-matching with InP is used for the base layer, the influence of alloy scattering is added to the above-mentioned compositional separation, and it is considered that the electron mobility is lowered.

An effective method for suppressing the aforementioned compositional separation of GaAsSb is to separate the Sb molar composition ratio of GaAsSb from 0.5 as much as possible, as can be seen from FIG. 3. Thus, it is possible to reduce the influence of the compositional separation which is a factor for lowering the electron mobility of GaAsSb. Furthermore, keeping the Sb molar composition ratio as far away from 0.5 as possible is also effective in reducing the influence of alloy scattering on the electron mobility of GaAsSb.

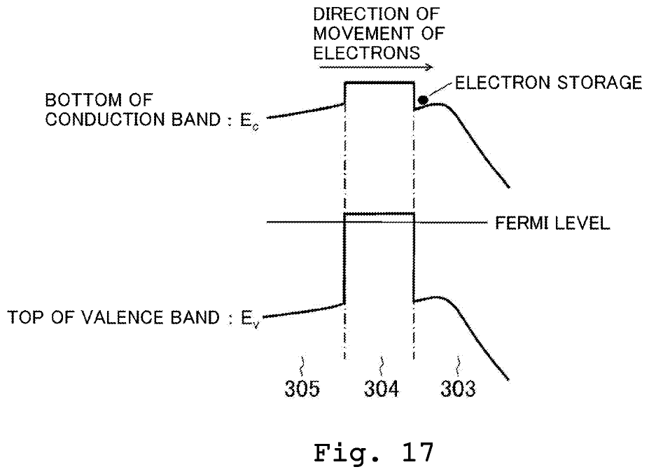

In GaAsSb, if only the influence of compositional separation and alloy scattering is reduced, it is sufficient to keep the Sb molar composition ratio away from 0.5. However, as described using FIG. 17, in the double hetero-junction bipolar transistor, it is necessary to reduce the band discontinuity between the base layer and the collector layer, and it is important to determine the Sb molar composition ratio in consideration of this.

The Sb molar composition ratio of GaAsSb effective for reducing band discontinuity between the base layer and the collector layer will be described below.

As described above, the difference between the calculation result of the band arrangement of GaAsSb and the measurement result by experiment is large, and it is difficult to obtain the band arrangement in the conduction bands of GaAsSb and InP, in which the Sb molar composition ratio is changed, from calculation. For this reason, the band discontinuity of GaAsSb and InP, in which the Sb molar composition ratio at 300 K is changed, was calculated, using the following method, based on a known report value by experiment at low temperature (10 K) in embodiments of the present invention.

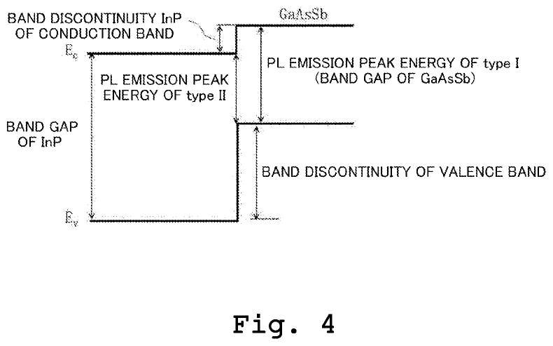

The hetero structure of GaAsSb and InP takes a band arrangement of type II as shown in FIG. 4. In the structure having this band arrangement, the carriers (electrons and positive holes) are thermally excited when the potential barrier is small in the vicinity of room temperature (to 300 K), and can overcome the potential barrier. Therefore, when the thickness of GaAsSb is small and carriers optically excited in GaAsSb immediately reach a hetero interface with InP, light emission by the inter-band transition of type II becomes dominant. Even in this case, when the thickness of GaAsSb is large, carriers optically excited in GaAsSb cannot reach the interface, and when recombination occurs in GaAsSb, light emission due to inter-band transition of type I can be observed.

On the other hand, when the photoluminescence (PL) is measured at a low temperature, the carrier is hardly affected by thermal excitation, and therefore, light emission due to inter-band transition of both type I and type II can be observed (for example, refer to NPL 3 and NPL 4).

As can be seen from FIG. 4, if the energies due to the inter-band transitions of type I and type II are known, the band discontinuity of the conduction band can be obtained by subtracting the emission energy of type II from the bandgap of GaAsSb (emission energy of type I). The problem is a method of reflecting the measurement result of photoluminescence at a low temperature on a value at room temperature. The inventors calculated the band discontinuity of the conduction band at 300 K based on the reported low temperature PL using the following method.

To estimate the band discontinuity in the conduction band at room temperature (300 K) based on the low-temperature measurements, it is necessary to consider the change in the bandgap of GaAsSb and InP due to temperature and also consider the conduction and valence bands changes due to temperature of band discontinuity. It is known that the change E_{g}(T) of the semiconductor bandgap E_{g} due to the temperature T can be expressed by Varshni's formula

“E_{g}(T)=E_{g}(T=0)−(αT²)/(T+β) (1)”.

In the formula (1), T is temperature in units of Kelvin, E_{g}(T) is the bandgap at temperature TK, E_{g}(T=0) is the bandgap at temperature 0K, and α and β are constants. α and β generally vary depending on the composition of a ternary or higher mixed crystal semiconductor but are exceptionally known to be constant in GaAsSb regardless of the Sb molar composition ratio (see Reference 4). Specifically, α=0.42 meV/K and β=189K. For InP, α=0.363 meV/K and β=162K.

Regarding the change in the band discontinuity of the conduction band and the valence band due to temperature, in the type I quantum well structure, a method is used in which the ratio of the band discontinuity between the conduction band and the valence band is constant regardless of temperature. It is also considered that a method in which the ratio of band discontinuity between the conduction band and the valence band is constant regardless of temperature is effective with respect to the hetero structure of type II.

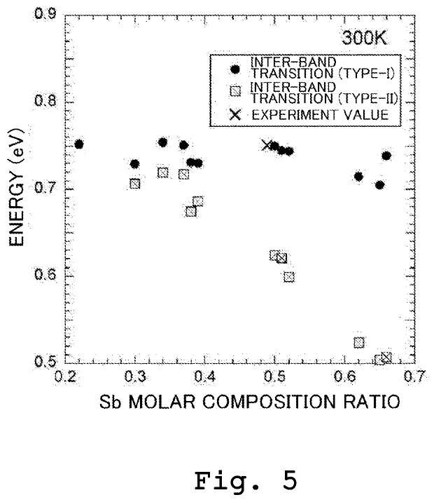

The inter-band transitions of type I and type II were determined at room temperature (300 K) based on reported low-temperature PL, using the method described above. FIG. 5 shows inter-band transitions of type I and type II at 300 K based on the experimental results at low temperature (10 K) in NPL 3. “X” in FIG. 5 is a value obtained by experiments performed to confirm the usefulness of the analysis method. Specifically, a sample was prepared by growing only GaAsSb with a thickness of 0.3 μm on InP and laminating it, and the energy of the type I inter-band transition was obtained from PL measurement of this sample at 300 K.

The experimental value is well coincident with the result calculated based on the low temperature experimental data. It is therefore considered that the method used in embodiments of the present invention for calculating the energy of the inter-band transition at room temperature from the low temperature data is useful.

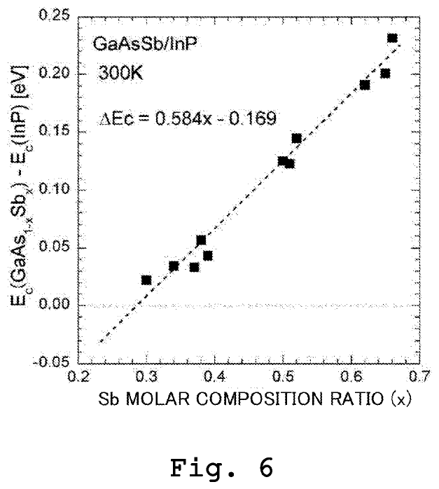

If the energy of the inter-band transition between the type I and the type II is known, the band discontinuity of the conduction band can be obtained. FIG. 6 shows the change of the GaAsSb/InP hetero structure at 300 K, which is band-discontinuity in the conduction band, depending on the Sb molar composition ratio of GaAsSb, obtained from FIG. 5. The line (dotted line) in FIG. 6 is obtained by approximating the data points with a straight line using the method of least squares. It can be seen from FIG. 6 that the data points are substantially along the straight line of this approximation. This approximate expression is expressed by ΔEc=0.584x−0.169 (eV), when the Sb molar composition ratio of GaAsSb is set as x and the band discontinuity of the conduction band is set as ΔEc.

The band discontinuity in the conduction band between GaAsSb (Sb molar composition ratio: about 0.49) lattice-matched to InP and InP is about 0.12 eV from the approximate formula. Therefore, as described using FIG. 17, when GaAsSb lattice-matched with InP is used as the base layer and InP is used as the collector layer, a potential notch structure is formed at the bottom of the conduction band of the collector layer. However, in this case, the band discontinuity in the conduction band is about 0.12 eV.

As can be seen from FIG. 6, the band discontinuity in the conduction band, when the Sb molar composition ratio of GaAsSb is 0.4, is about 0.06 eV, which can be almost half that of GaAsSb lattice-matched to InP. Therefore, if the Sb molar composition ratio of GaAsSb is set to 0.4 V or less, the influence of the potential notch structure described above can be reduced.

The band discontinuity in the conduction band is reduced by further reducing the Sb molar composition ratio of GaAsSb. However, when the Sb molar composition ratio becomes smaller than 0.3, the sign changes from positive to negative. This means that the energy level of the bottom of the conduction band of the GaAsSb base layer is lower than the energy level of the bottom of the conduction band of the collector layer of InP. In this case, a potential barrier in a conduction band is formed between the base layer and the collector layer, and it becomes an obstacle to electron transfer, which causes deterioration of device characteristics.

From the above, when the base layer is made of GaAsSb and the collector layer is made of InP, the Sb molar composition ratio of GaAsSb constituting the base layer is desirably set to 0.3 or more and 0.4 or less.

As can be seen from FIG. 6, when the base layer is made of GaAsSb and the collector layer is made of InP, a potential barrier against electron transfer occurs when the Sb molar composition ratio of GaAsSb is 0.3 or more. This potential barrier can be reduced by replacing the emitter layer from InP with a material having a large band gap such as InGaP, InAlP, and InAlAs, as mentioned above. Among InGaP, InAlP, and InAlAs, InGaP is considered to be useful from the viewpoint of reliability because it is a material which does not contain Al which tends to cause oxidation.

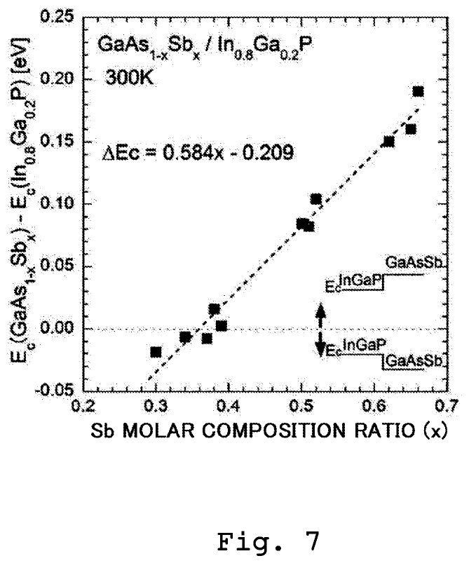

The results of the examination of the band discontinuity of the conduction band when the emitter layer is changed from InP to InGaP will be described below. FIG. 7 shows the change in band discontinuity in the conduction band between the emitter layer made of In_{0.8}Ga_{0.2}P and the base layer made of GaAsSb depending on the Sb molar composition ratio of GaAsSb. The line (dotted line) in FIG. 7 is obtained by approximating the data points with a straight line using the method of least squares. The approximate line of FIG. 7 is basically a line obtained by translating the approximate line of FIG. 6.

As can be seen from FIG. 7, in the GaAsSb/In_{0.8}Ga_{0.2}P hetero-structure, the band arrangement changes from type II to type I, and the Sb molar composition ratio is about 0.36. This means that, when the emitter layer is made of In_{0.8}Ga_{0.2}P and the base layer is made of GaAsSb, if the Sb molar composition ratio of GaAsSb is set to 0.36 or less at the interface between the emitter layer and the base layer, no potential barrier against electron transfer occurs.

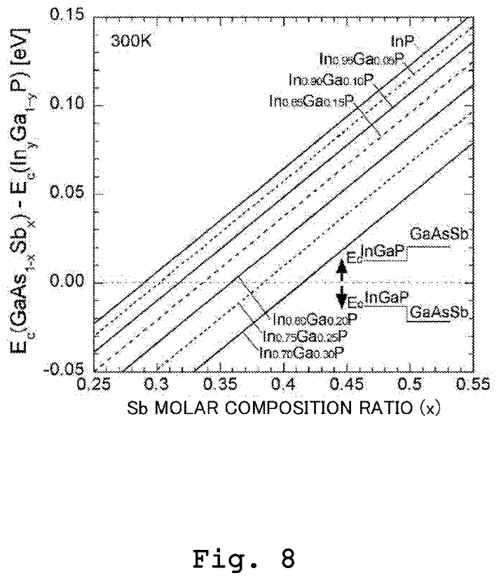

The Ga molar composition ratio of this InGaP is, of course, not limited to 0.2. FIG. 8 shows a band discontinuity of the conduction band between InGaP and GaAsSb when the Ga molar composition ratio of InGaP is changed to 0, 0.05, 0.10, 0.15, 0.20, 0.25, and 0.30. By increasing the Ga molar composition ratio of InGaP, it is possible to increase the Sb molar composition ratio of GaAsSb in which the above-mentioned band arrangement changes from type II to type I. Specifically, the Sb molar composition ratio is about 0.39 when the Ga molar composition ratio of InGaP is 0.25, and the Sb molar composition ratio is about 0.42 when the Ga molar composition ratio of InGaP is 0.30.

Thus, by increasing the Ga molar composition ratio using InGaP for the emitter layer, it is possible to increase the Sb molar composition ratio of the GaAsSb base layer for reducing the potential barrier against electron transfer between the emitter layer and the base layer.

However, when InGaP is grown on InP, since lattice distortion is added to the crystal lattice of InGaP, the Ga molar composition ratio and thickness are limited. Also for GaAsSb, the Sb molar composition ratio of lattice-matching is about 0.49, and when the Sb molar composition ratio is made smaller than that, lattice distortion is added to the crystal lattice.

A method of reducing the lattice distortion actually applied to InGaP and GaAsSb and the influence of the lattice distortion in the device structure will be described below.

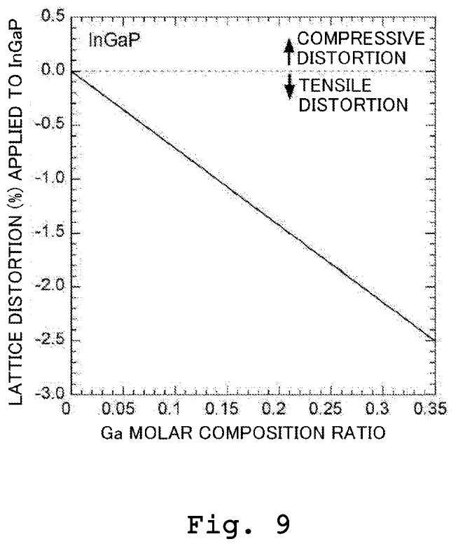

FIG. 9 shows a change in lattice distortion due to the Ga molar composition ratio of InGaP on InP. In the vertical axis of FIG. 9, the compression distortion is applied when the sign is positive, and the tensile distortion is applied when the sign is negative. As can be seen from FIG. 9, a tensile distortion is applied to InGaP with the increase in the Ga molar composition ratio. Specifically, a tensile distortion of about 0.7% when the Ga molar composition ratio is 0.1 and about 1.4% when the Ga molar composition ratio is 0.2 is applied to the crystal lattice. Regarding InGaP on InP, it is known that crystal growth can be performed without causing lattice relaxation up to a Ga molar composition ratio of about 0.25 (tensile distortion: about 1.8%) (see Reference 5).

Therefore, if the Ga molar composition ratio of InGaP is set to 0.25 or less, it can be grown on InP. As described above, it is known that if the band discontinuity in the conduction band is about 100 MeV, the electron transfer is hardly affected by the band discontinuity in the conduction band. When the Ga molar composition ratio of InGaP is 0.25, the condition for the band discontinuity of the conduction band to be 100 meV or less in FIG. 8 is a case where the Sb molar composition ratio of GaAsSb is 0.53 or less. Therefore, it is desirable that the Sb molar composition ratio of the GaAsSb base layer be 0.53 or less.

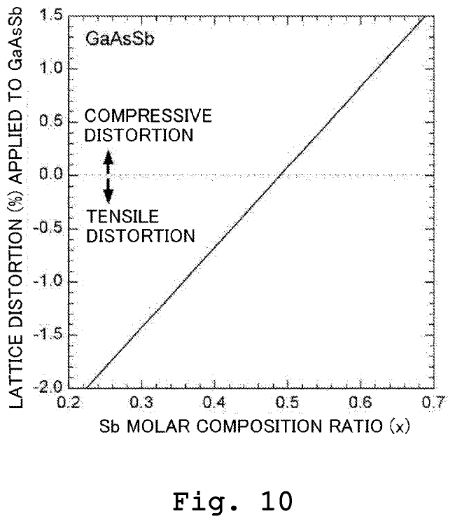

FIG. 10 shows a change in lattice distortion due to the Sb molar composition ratio with respect to GaAsSb on InP. As described above, when the base layer is made of GaAsSb, the condition for maintaining the type II band alignment with the InP collector layer while suppressing the effects of composition separation and alloy scattering is that the Sb molar composition ratio of GaAsSb is in the range of 0.3 or more and 0.4 or less.

From FIG. 10, it can be seen that a tensile distortion of 0.7% to 1.4% is applied to the crystal lattice of GaAsSb when the Sb molar composition ratio of GaAsSb is in the range of 0.3 or more and 0.4 or less. Therefore, when the base layer is made of GaAsSb having a composition in which the Sb molar composition ratio is 0.3 or more and 0.4 or less and the thickness is increased, since the tensile distortion is applied to the entire layer structure, lattice relaxation occurs, and crystal defects occur.

However, in the double hetero-junction bipolar transistor, band discontinuity in the conduction band is a problem basically at the interface between the emitter layer and the base layer and the interface between the base layer and the collector layer, and these interfaces may have the desired band arrangement. Specifically, the Sb molar composition ratio of the GaAsSb base layer is continuously increased toward the emitter layer. The InGaP emitter layer is also configured such that the Ga molar composition ratio continuously increases toward the base layer.

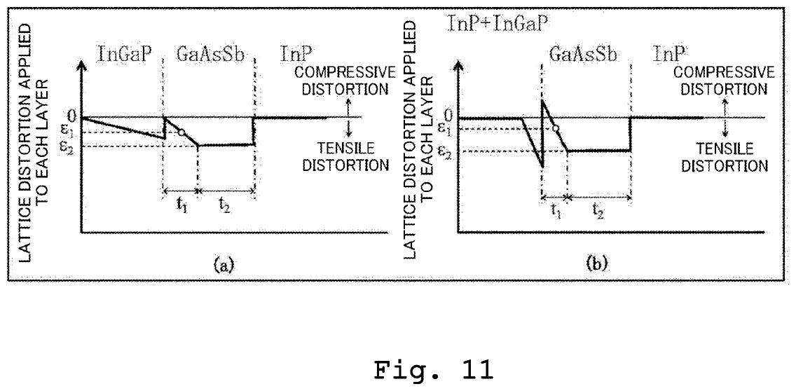

FIG. 11 shows a change in lattice distortion in the layer in a structure in which the Sb molar composition ratio of the GaAsSb base layer and the Ga molar composition ratio of the InGaP emitter layer are changed in this way. FIG. 11(a) shows a case where the emitter layer is formed of only InGaP. FIG. 11(b) shows a case where an InGaP layer is disposed in a part of the emitter layer. Both of them are increased so that the Ga molar composition ratio in the emitter layer becomes maximum in the vicinity of the interface with the base layer.

In either case, the thickness of the InGaP emitter layer can be adjusted by changing the rate of increase in the Ga molar composition ratio. Therefore, the thickness of the InGaP emitter layer can be reduced if the rate of increase in the Ga molar composition ratio is increased. Therefore, the influence of lattice distortion in the InGaP emitter layer can be relatively easily reduced. On the other hand, the thickness of the GaAsSb base layer cannot be easily reduced. This is because the base resistance increases as the thickness of the GaAsSb base layer decreases.

In the structure shown in FIG. 11, a region of the GaAsSb base layer having a small Sb molar composition ratio and a large tensile distortion is a layer that is close to the collector layer. The Sb molar composition ratio of the GaAsSb base layer is constant in a region close to the collector layer, but is increased toward the emitter layer from the middle, and thus, the tensile distortion is reduced in this region. Therefore, the structure shown in FIG. 11 is effective in reducing the tensile distortion applied to the entire GaAsSb base layer.

The tensile distortion applied to the entire base layer will be described below. In the GaAsSb base layer of FIG. 11, when the thickness of a region in which the Sb molar composition ratio near the emitter layer continuously changes is defined as t₁, the absolute value of the average value of the tensile distortion is defined as ε₁, the thickness of a region in which the Sb molar composition ratio near the collector layer is constant is defined as t₂, and the absolute value of the tensile distortion is defined as ε₂, an average value ε* of the tensile distortion as the whole GaAsSb base layer can be expressed by

“ε*=(ε₁xt₁+ε₂xt₂)/(t₁+t) (2)”.

In the GaAsSb base layer, the place (region) in which the tensile distortion becomes large is a region close to the collector layer, and the absolute value ε₂ of the tensile distortion is a value between 0.7% and 1.4%, as described above. Since the Sb molar composition ratio of the GaAsSb base layer becomes larger toward the emitter layer, the tensile distortion ε₁ in this region becomes smaller than ε₂. Therefore, the average value ε* of the tensile distortion can be smaller than ε₂ and can be suppressed to 1% or less.

For example, in the GaAsSb base layer, first, the Sb molar composition ratio in a region close to the emitter layer is set to 0.52. Further, the Sb molar composition ratio is continuously decreased to 0.3 by a thickness of 15 nm (corresponding to t₁) toward the collector layer. Thereafter, the Sb is grown to a thickness of 15 nm (corresponding to t₂) while keeping the Sb molar composition ratio at 0.3. In the case of this structure, ε₁=0.6% and ε₂=1.4%. In this case, if the average value ε* of the tensile distortion is calculated by Formula (2), 1.0% is obtained.

As described above, the average value ε* of the tensile distortion of the entire base layer can be adjusted by the Sb molar composition ratio and the thickness of the GaAsSb base layer shown in FIG. 11. However, in this case, as the thickness of the base layer as a whole increases, the influence of lattice distortion increases, and crystal defects occur. That is, there is an upper limit in the allowed thickness of the entire base layer.

In order to examine the upper limit of the allowable thickness of the entire base layer, a sample was prepared by growing GaAsSb on InP with a tensile distortion of 1% (Sb molar composition ratio of 0.36) and varying the thickness, and X-ray diffraction patterns and microscopic PL mapping measurements of the prepared samples were performed. For the growth of the sample, an organometallic molecular beam epitaxy method is used, and InP having a thickness of 3 nm is grown on the surface of GaAsSb to suppress oxidation.

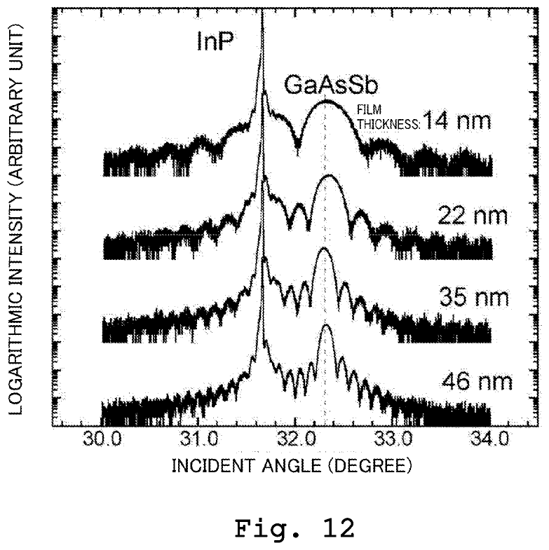

FIG. 12 shows the results of the measurement of the X-ray diffraction pattern described above. Although the peak near the incident angle of 32.3 degrees is due to the X-ray diffraction from the GaAsSb layer, it can be seen that the angle of this peak is almost constant regardless of the thickness. This means that, in GaAsSb, even if the tensile distortion is 1%, a large lattice relaxation does not occur.

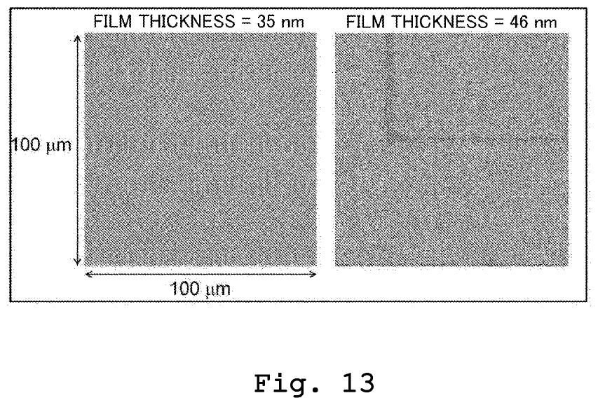

FIG. 13 shows the measurement results of the microscopic PL mapping for a sample in which GaAsSb having a tensile distortion of 1% and a thickness of 35 nm and 46 nm is grown. In FIG. 13, it means that the PL emission intensity is smaller in a region having higher density. In the case of a sample having a thickness of 35 nm of GaAsSb, dark lines and dark points having a small PL emission intensity were not observed. FIG. 13 shows an example in which the measurement range is 100 μm×100 μm, but there was no dark line or dark point even when measurement was performed over a wide range of the sample.

On the other hand, in the case of a sample having a thickness of 46 nm, only one dark line as shown in FIG. 13 was observed by measuring several μm in all directions. Such dark lines are well observed when lattice relaxation occurs and crystal defects occur.

From the above, it can be seen that, when GaAsSb having a tensile distortion of 1% is used, growth can be performed without causing crystal defects if the thickness is up to 35 nm. As described above, in the structure in which the Sb molar composition ratio is changed in the GaAsSb base layer as shown in FIG. 11, it is easy to set the average value of the tensile distortion applied to GaAsSb to 1% or less. Therefore, when the thickness of the GaAs Sb base layer is set to 35 nm or less as a whole, the layer structure for the device can be easily grown without causing crystal defects.

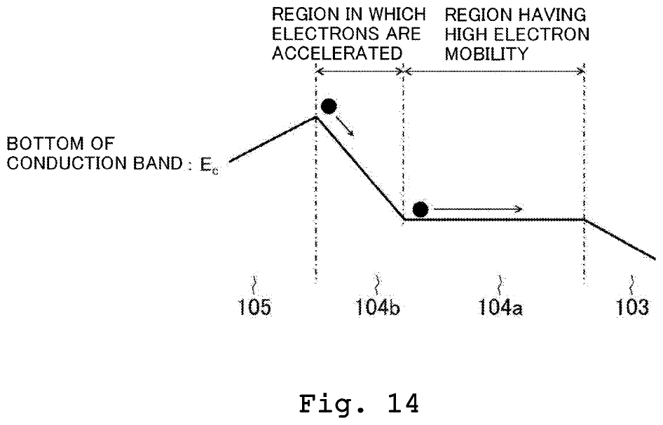

Next, the advantage of using the structure shown in FIG. 11 as the GaAsSb base layer to improve the device characteristics will be described. In the structure shown in FIG. 11, the Sb molar composition ratio of the GaAsSb base layer has a constant value between 0.3 and 0.4 in the region close to the collector layer, but is continuously increased to a value of 0.53 or less from the middle of the base layer to the interface with the emitter layer. As the Sb molar composition ratio of GaAsSb increases, the energy position of the bottom of the conduction band becomes higher. Therefore, when the GaAsSb base layer having the structure shown in FIG. 11 is used, the energy position at the bottom of the conduction band is as shown in FIG. 14. In this case, a pseudo electric field is generated in the base layer close to the emitter layer.

When electrons enter the base layer from the emitter layer, they are accelerated by the pseudo electric field. However, in this region, since the Sb molar composition ratio is large and the electron mobility is small due to the influence of compositional separation and alloy scattering, there is a limit to acceleration of electrons by a pseudo electric field. On the other hand, in the structure shown in FIG. 11, a GaAsSb layer having a small Sb molar composition ratio which can be expected to have a high electron mobility is disposed in a region close to the collector layer. Further, the Sb molar composition ratio in this region is constant, and the tensile distortion is not increased toward the collector layer like a region to which a pseudo electric field is applied, and the tensile distortion is also constant.

Therefore, in the GaAsSb base layer, electrons are accelerated while suppressing the occurrence of crystal defects due to lattice distortion, and high electron mobility can be utilized. In this structure, the GaAsSb base layer has a degree of freedom of design which is not in a structure using a conventional GaAsSb base layer, such as the thickness of a region in which the Sb molar composition ratio is constant and a region in which it continuously changes, and the increase rate of the Sb molar composition ratio in the region in which the Sb molar composition ratio continuously changes, and the current gain cut-off frequency can be increased by appropriately setting these values.

As described above, it is understood that the use of the layer structure of the double hetero-junction bipolar transistor according to the embodiment improves the device characteristics. Although the above description shows an example in which the Sb molar composition ratio of the GaAsSb base layer is constant in a region close to the collector layer, it is not always necessary to be constant if the average value of the tensile distortion applied to GaAsSb is equal to or less than 1 and the total thickness of the GaAsSb base layer is equal to or less than 35 nm, and the region in which the Sb molar composition ratio of the GaAsSb base layer is constant is also effective in a structure in which the Sb molar composition ratio is gradually decreased toward the collector layer. This is because the effect that even if the Sb molar composition ratio of the GaAsSb base layer is small and the Sb molar composition ratio is small in the range in which the influence of lattice distortion is small, the influence of the miscibility gap and the alloy on the mobility of electrons is small is utilized.

In the above embodiment, although the case where the base layer is made of only GaAsSb is shown, it is needless to say that, if the average value of tensile distortion applied to the base layer is 1% or less, and the total thickness of the GaAsSb base layer is 35 nm or less, the base layer is not necessarily formed of only GaAsSb, and it is effective even if a small amount of In is contained within a range that does not significantly affect the magnitude of tensile distortion and electron mobility.

As described above, according to embodiments of the present invention, since the Sb molar composition ratio of the base layer made of the group III-V compound semiconductor containing Ga, As, and Sb is decreased in the thickness direction from the emitter layer side to the middle of the base layer and is made constant from the middle of the base layer to the collector layer, expected device characteristics can be obtained in a hetero-junction bipolar transistor using GaAsSb for the base layer.

Also, it is apparent that embodiments of the present invention are not limited to the embodiments described above, and many modifications and combinations can be carried out by those having ordinary knowledge in the art within the technical idea of embodiments of the present invention.

### REFERENCES

Reference 1—T. H. Chiu et al., “Molecular beam epitaxy of GaSb_{0.5}As_{0.5} and AlxGa₁₋ₓSbyAs_{1-y} lattice matched to InP”, Applied Physics Letters, vol. 46, No. 4, pp. 408-410, 1985.
Reference 2—K. Miura et al., “The growth of high quality GaAsSb and type-II InGaAs/GaAsSb superlattice structure”, Journal of Applied Physics, vol. 113, 143506, 2013.
Reference 3—V. S. Sorokin et al., “Novel approach to the calculation of instability regions in GaInAsSb alloys”, Journal of Crystal Growth, vol. 216, pp. 97-103, 2000.
Reference 4—R. Lukic-Zrnic et al., “Temperature dependence of the band gap of GaAsSb epilayers”, Journal of Applied Physics, vol. 92, No. 11, pp. 6939-6941, 2002.
Reference 5—M. Kahn and D. Ritter, “Strain relief by long line defects in tensile GayIn_{1-y}P layers grown on InP substrates”, Applied Physics Letters, vol. 79, No. 18, pp. 2028-2930, 2001.

### REFERENCE SIGNS LIST

101 Substrate
102 Sub-collector layer
103 Collector layer
104 Base layer
104a First base layer
104b Second base layer
105 Emitter layer
105a InGaP layer
105b Upper emitter layer
106 Emitter cap layer
111 Collector electrode
112 Base electrode
113 Emitter electrode

1.-3. (canceled)

4. A hetero-junction bipolar transistor comprising:
a substrate comprising InP;
a collector layer on the substrate and comprising a first group III-V compound semiconductor;
a base layer on the collector layer and comprising a second group III-V compound semiconductor comprising Ga, As, and Sb; and
an emitter layer on the base layer and comprising a third group III-V compound semiconductor different from the second group III-V compound semiconductor;
wherein an Sb molar composition ratio of the base layer decreases from a side closest to the emitter layer to a middle of the base layer in a thickness direction; and
wherein the Sb molar composition ratio of the base layer is constant from the middle of the base layer to a side closest to the collector layer in the thickness direction.

5. The hetero-junction bipolar transistor according to claim 4, wherein:
the Sb molar composition ratio of the base layer is in a range from 0.49 to 0.53 in a vicinity of an interface with the emitter layer;
the Sb molar composition ratio of the base layer is in a range from 0.3 to 0.4 in a vicinity of an interface with the collector layer; and
the base layer has a thickness of 35 nm or less.

6. The hetero-junction bipolar transistor according to claim 5, wherein:
the emitter layer comprises an InGaP layer comprising InGaP in a part in the thickness direction; and
a Ga molar composition ratio of the InGaP layer increases toward the base layer in a range from greater than 0 to 0.25.

7. The hetero-junction bipolar transistor according to claim 4, wherein:
the emitter layer comprises an InGaP layer comprising InGaP in a part in the thickness direction; and
a Ga molar composition ratio of the InGaP layer increases toward the base layer in a range from greater than 0 to 0.25.

8. A method of forming a hetero-junction bipolar transistor, the method comprising:
forming a collector layer on a substrate, wherein the collector layer comprises a first group III-V compound semiconductor and the substrate comprises InP;
forming a base layer on the collector layer, wherein the base layer comprises a second group III-V compound semiconductor comprising Ga, As, and Sb; and
forming an emitter layer on the base layer, wherein the emitter layer comprises a third group III-V compound semiconductor different from the second group III-V compound semiconductor;
wherein an Sb molar composition ratio of the base layer decreases from a side closest to the emitter layer to a middle of the base layer in a thickness direction; and
wherein the Sb molar composition ratio of the base layer is constant from the middle of the base layer to a side closest to the collector layer in the thickness direction.

9. The method according to claim 8, wherein:
the Sb molar composition ratio of the base layer is in a range from 0.49 to 0.53 in a vicinity of an interface with the emitter layer;
the Sb molar composition ratio of the base layer is in a range from 0.3 to 0.4 in a vicinity of an interface with the collector layer; and
the base layer has a thickness of 35 nm or less.

10. The method according to claim 9, wherein:
the emitter layer comprises an InGaP layer comprising InGaP in a part in the thickness direction; and
a Ga molar composition ratio of the InGaP layer increases toward the base layer in a range from greater than 0 to 0.25.

11. The method according to claim 8, wherein:
the emitter layer comprises an InGaP layer comprising InGaP in a part in the thickness direction; and
a Ga molar composition ratio of the InGaP layer increases toward the base layer in a range from greater than 0 to 0.25.
